(19) United States
(12) Patent Application Publication
(10) Pub. No.: US 2011/0083721 A1
(43) Pub. Date: Apr. 14, 2011

(54) CONCENTRATING PHOTOVOLTAIC SYSTEM

(76) Inventor: Behzad IMANI, San Mateo, CA (US)

(21) Appl. No.: 12/622,348

(22) Filed: Nov. 19, 2009

Related U.S. Application Data
(60) Provisional application No. 61/199,769, filed on Nov. 20, 2008.
(60) Provisional application No. 61/200,453, filed on Nov. 28, 2008.

(51) Int. Cl. H01L 31/052

(52) U.S. Cl. 136/246

(57) ABSTRACT

A solar cell concentrating apparatus includes a parabolic or similar reflector focusing a beam of light on an array of photovoltaic cells to generate electric current. The reflector includes a large number of hexagonal mirrors each provided with an infra red reflective coating. A suitable reflective coating material is aluminum oxide, but a number of others are well known. Further aspects of the apparatus include use of a Fourier transform lens to alter an intensity profile of the light beam incident on the solar cells, and/or a beam altering device including a bundle of optical fibers that are interleaved and of varying lengths, for the same purpose.

### CROSS-REFERENCE TO RELATED APPLICATIONS

This application claims priority to U.S. Provisional Applications No. 61/199,769, filed Nov. 20, 2008, and 61/200,453, filed Nov. 28, 2008 incorporated herein by reference in their entirety.

### FIELD OF THE INVENTION

This disclosure relates to generation of electricity by means of photovoltaic cells and more particularly to a concentrator apparatus whereby sunlight is concentrated on an array of photovoltaic cells.

### BACKGROUND

Concentrating photovoltaic apparatuses are well known in the field of electric current generation. See for instance WO2009/002281A2 published Dec. 31, 2008, inventor Jan ZUPA, disclosing a parabolic concentrating photovoltaic converter illustrated in a perspective view in present FIG. 1. This includes a large offset parabolic assembly of a number of rectangular shaped mirrors 3 with a concentrating photovoltaic (solar) cell array 7 in the focusing area of the minor assembly. A base 13 is provided; struts 11 support the cell array 7.

FIG. 2 illustrates in somewhat a schematic fashion a cross-sectional view of a similar solar concentrating apparatus disclosed in U.S. Patent Publication US2009/0032103A1 published Feb. 5, 2009, inventor Binxuan Y I. This includes a plurality of solar cells 21 mounted on a support 22. Support 22 is on the center of a parabolic shaped mirror base 23 which is rotationally symmetric about axis A-A. The parabolic mirror base 23 includes a large number of relatively small plane mirrors 26 mounted on the inner side of the minor base 23. The mirrors are, e.g., one inch (2.54 cm) square in one embodiment. The solar cells 21 are arranged around a focus point of reflected light rays from the plane minors 26. A number of heat sinks 24 are provided on the outer side of the minor base 23 for cooling purposes. This apparatus is somewhat smaller in size than that of FIG. 1, but otherwise similar. Both the above patent publications are incorporated herein by reference in their entireties.

In this field, a typical reflector assembly size is 0.75 to 10 meters in diameter, but this is not limiting. Such arrangements are generally well known in a number of variations. For instance, some mirror assemblies include a large number of small planar mirrors as described above. In other cases the minor assembly is a single reflective surface parabolic bowl. Both are well known to exhibit undesirable optical non-uniformities due to material and manufacturing variations.

### SUMMARY

There are several deficiencies with such photovoltaic concentrating apparatuses. One is that in order to minimize Ohmic (resistant) electrical losses in generating the electric current, typically a number of photocells (synonymous with photovoltaic or solar cells) are electrically connected in series to produce a higher voltage output. However, this means that all the cells have their photocurrents limited by the cell with the weakest current due to the serial arrangement. The individual photocurrents vary with the size of the active/illuminated area, the quality of the photovoltaic semiconductors in the individual cells, and the non-uniformity of the illumination which is characteristic of such concentrators due to optical non-uniformities. Note that the last is a particular problem since optical uniformity of the light beam at the focal point of the optical system is often poor.

Typically these problems, while recognized, have been addressed by developing individual optics for each photocell in the array, such as a set of lenses such as Fresnel lens or other types of lens, or by otherwise correcting the optics, that is tuning the optics individually to try to make the focal plane of the optical system as uniform and aberration-free as possible in optical terms. Of course both of these solutions involve relatively expensive optics and also make mass production difficult.

The technical problem can be characterized as imaging a circular object (the sun) on what is, in the prior art, a square solar cell array. Aspects of the present disclosure are intended to use the light beam energy more efficiently to maximize the efficiency of the solar cell array.

So the present system, referred to here as a photo-current balancing system, in some embodiments uses a photocell arrangement which complements any optical system aberrations rather than trying to eliminate such aberrations. In one embodiment, an optical system with circular symmetry is matched with a photocell array in the general shape of a circle or polygon divided into wedges, such as slices of a pie. Each wedge is one photocell. The photo-currents may be balanced by displacing the illumination centroid near the center of the pie shaped array using feedback from the array, and accordingly mechanically moving the solar cell array.

Another embodiment matches the photocell geometry to the Seidel aberrations of the optical system, that is the mirrors. The photocurrents are then balanced by adjusting, not only the centroid displacement, but also the defocus, astigmatism, and coma of the optical system by moving the solar cell array relative to the reflector (minors). This has the advantage of allowing for cost savings in constructing such a system since lower quality optics can be used without compromising system efficiency in terms of electrical current generation.

In one embodiment, the photocell array includes a plurality of triangular (wedge) shaped (in plan view) individual photocells which are otherwise of conventional construction. They are arranged like slices of a pie. Each slice (triangle) is of approximately the same surface area. The base of each slice may be curved as in a pie wedge or straight as in a triangle. The term “triangular” here generally refers to pie wedges, true triangles and similar shapes. Arranged peripherally around the central triangular shaped cells is a set of trapezoid shaped solar cells, each such trapezoidal cell having its narrower base adjacent the base of one of the triangular cells and its wider base spaced away from one of the triangular cells. Thus there is one trapezoidal cell for each triangular solar cell. In one embodiment, the trapezoidal cells are of a larger surface area than the central triangular cells since typically the light beam being provided from the optical system is less intense at the edge of the illumination spot.

Gaussian light beams are well known in optics, where the term Gaussian describes a variation in the irradiance along a line perpendicular to the direction of light beam propagation and through the center of the light beam. Typically a Gaussian beam is symmetrical about the light beam's central axis and has its greatest intensity along the axis, falling off geometrically as one moves away from the axis in both directions. For instance, the irradiance I is symmetric about the beam axis and varies radially outward from the axis (variable r) with the form:

I(r)=I₀e^{-2r}^{²}^{/r}^{₁}^{²}

where r₁ is the quantity that defines the radial extent of the beam. This value is, by definition, the radius of the beam where the irradiance is 1/e² of the value of the beam axis, I₀. Of course this is just one example of a Gaussian beam and generally “Gaussian” here refers to the characteristic that the beam is more intense at the center than away from the center axis. Moreover, the present beam need not be Gaussian.

Moreover in addition to the layout of the solar cells, the solar cell concentrator of which the solar cell array is one component, includes a support for the solar cell array. The support includes a cooling plate (heat sink) in thermal contact with the obverse side of the solar cells. In one version, the heat sink defines a set of channels through which a cooling fluid, such as water or air, or another fluid may circulate via a conventional manifold to prevent overheating of the solar cell array, due to the intense incident light beam. Suitable conventional electrical current conductors are provided electrically in contact with the solar cells, e.g., at their outer perimeters or undersides, as is conventional. Moreover the series/parallel electrical connections of the solar cells to one another may be configured to provide optimum voltage and current output.

### BRIEF DESCRIPTION OF THE DRAWINGS

FIGS. 1 and 2 show two respective prior art solar cell concentrators.

FIG. 3 shows a plan view of the present solar cell array.

FIG. 4 shows a plan view of one of the trapezoidal solar cells of the array of FIG. 3.

FIG. 5 shows a plan view of one of the triangular solar cells of the array of FIG. 3.

FIG. 6 shows a cross sectional view of the solar cell array of FIG. 3.

FIG. 7 shows a solar concentrator with a Fourier transform lens.

FIG. 8 shows a fiber optic bundle adapted to shape a beam for a solar cell concentrator.

FIG. 9 shows an arrangement of the solar cells with feedback.

### DETAILED DESCRIPTION

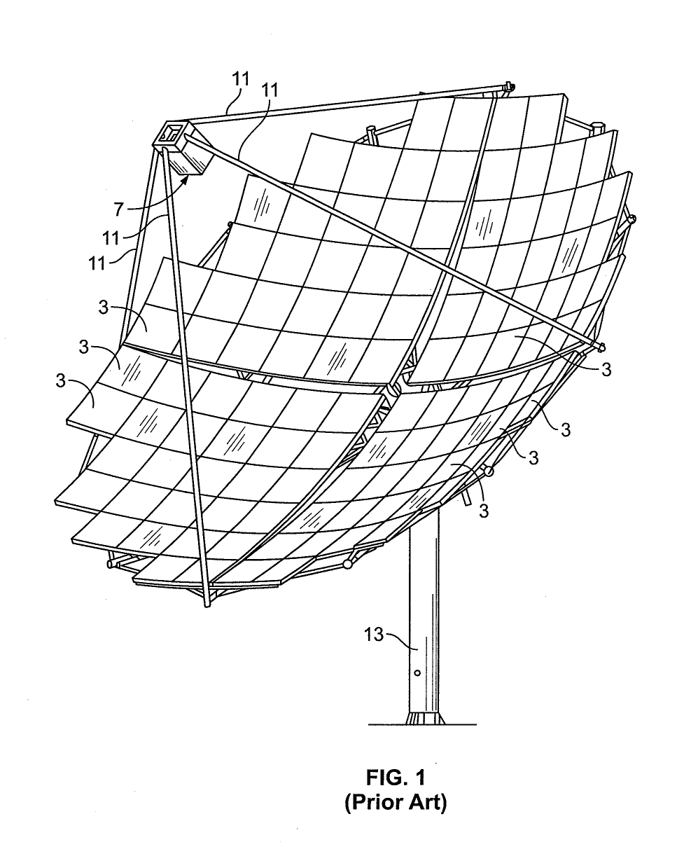

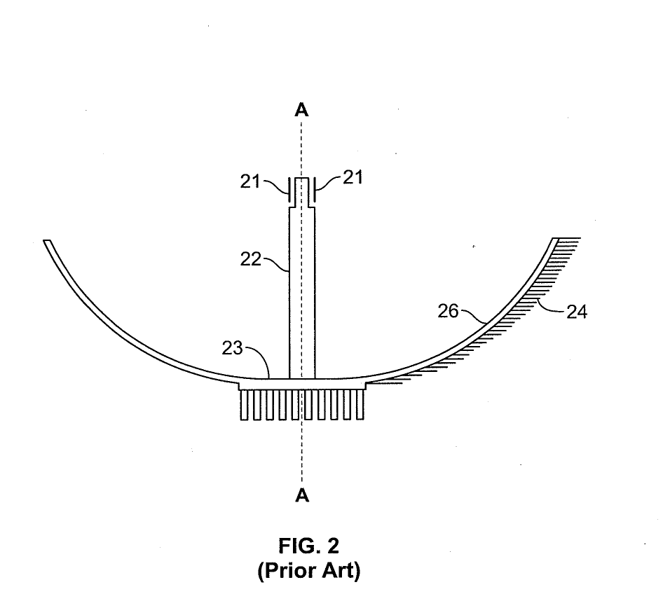

FIG. 3 shows in one embodiment the present solar cell array 30 in plan view as would face a reflector (mirror) structure similar to that of FIGS. 1 and 2. The minor reflectors of FIG. 1 or 2 and the strut or struts which hold solar cell array 30 in position are not shown in FIG. 3 as being conventional. In this example solar cell array 30 includes a plurality of triangular shaped solar cells 36a-36h, arranged side by side to define an octagon. In this case there are eight such cells, so each defines in this case a 45° isosceles triangle. Arranged around the perimeter of the triangular shaped solar cells is a plurality of trapezoidal shaped solar cells 32a-32h, there being here one trapezoidal solar cell associated with each triangular solar cell. This one-to-one relationship is only exemplary. This depicts a 16 cell solar array. If these are 16 typical solar cells each outputting a current having a potential of about 2.6 volts, the total voltage output of all the cells when electrically connected in series is about 42 volts.

Detail of one of the triangular shaped solar cell is shown in FIG. 5, where dimensions G and F, are respectively in one (merely exemplary) embodiment 1.16 cm and 1.4 cm.

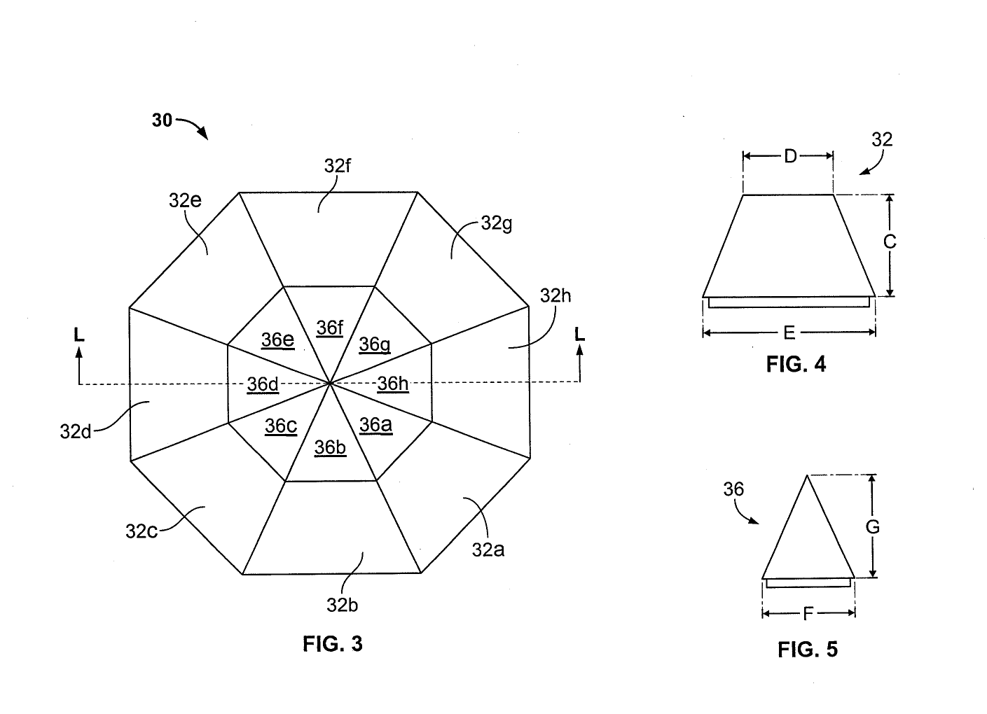

FIG. 4 shows a similar plan view of one of the trapezoidal cells 32, where the three dimensions C, D, and E are for example respectively 1.4 cm, 1.36 cm, and 2.32 cm.

The nature and number and composition and type of the individual solar cells are not limited here. They may be any type of conventional type solar cells, such as conventional mono or poly-crystalline (wafer type) solar cells, thin film solar cells, single junction photocells, multi-junction photocells, etc. The cells in any one array need not be of the same type. Hence the nature of the solar cells in terms of their semiconductor activity and electrical output is conventional here in terms of the individual cells. While cells having the triangular or trapezoidal shapes are not believed to be commercially available, cells of such shapes may be manufactured using conventional methods. Alternatively, although care must be taken to preserve electrical contact with the cell conductors, one may obtain commercially available square or rectangular shaped cells and conventionally saw (cut) them into the requisite shapes. For instance, one square shaped cell cut along its diagonal will provide two 90° isosceles triangular cells. Such square or rectangular cells are commercially available from a variety of vendors.

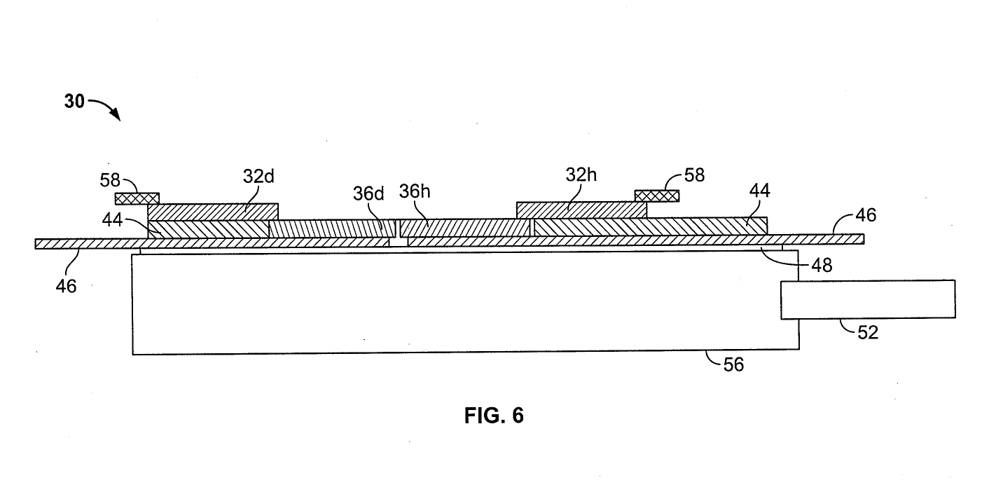

FIG. 6 shows a cross section along line L-L of solar cell array 30 of FIG. 3. FIG. 6 shows two of the triangular solar cells 36d, 36h and the two associated outer trapezoidal cells 32d, 32h. In this case the trapezoidal cells 32d, 32h are displaced in terms of their plane from the triangular cells 36d, 36h. The displacement is not required; it is used here for providing sufficient space for the electrical connections to each cell. Also shown here (but not in FIG. 3 for simplicity) are such conventional electrical current conductors 46 (e.g., bus bars) and 58 (e.g., metal coatings) in contact with respectively the triangular cells 36 and trapezoidal cells 32. A layer of thermally conducting electrical insulator 44 for example, metal oxide or silicone based heat sink compound, provides thermal contact to electrical conductor 46 for a heat path.

Electrical conductor 46 in turn conducts the heat into the heat sink 56, which is for instance an aluminum plate of suitable size and thickness depending on the expected heat load, to absorb the heat caused by the incident light on the solar cells. It is to be understood that the amount of heat so generated may be considerable. To aid in heat dissipation, in some embodiments heat sink 56 defines a number of internal channels or conduits (not shown) for carrying a cooling fluid, such as, e.g., air, water, or lithium bromide solution. In this case tubing bundle 52 is provided for conducting the cooling fluid into and out of the heat sink 56, for instance via a conventional manifold, to a radiator or perhaps to some sort of external co-generation system to use the heat productively, e.g., to operate air conditioning or provide hot water. In this example a clearance (spacing) 48 is provided between the cooling plate 56 and the lower conductor layer 46, but this is not required.

Further, in one embodiment a “pseudo” integrating sphere is used as a light trap for any light not captured by the solar cell array. (An integrating sphere is a hollow sphere coated internally with a reflective and diffusing material.) Here the pseudo integrating sphere traps the light and converts it to heat. The heat is transferred to the heat sink 56 with which the sphere is in thermal contact, for improved efficiency.

The absolute and relative size (surface area) of each cell is selected in some embodiments according to particular goals, as explained hereinafter. In one embodiment, the active surface area which in turn determines their current output is adjusted during design or construction of the apparatus to match the expected or measured non-uniformity of illumination in terms of local variations in the intensity of the incident light beam from the reflector assembly. It is known that both imaging and non-imaging solar collectors typically produce non-uniform illumination, which is more intense at the central region than along its periphery. So, as shown in FIG. 3 the outer cells have relatively larger surface areas than the inner cells. In other embodiments the light beam may exhibit a plurality of local intensity variations, and the cell surface area may be varied in a more complex fashion accordingly.

FIG. 3 depicts two concentric rings of cells, the inner triangular cells with the peripheral trapezoidal cells. A third set of cells may be provided located peripheral to the trapezoidal cells for an apparatus with a larger diameter light beam, in another embodiment. Further sets of cells may also be provided moving radially outward from the center of the cell array.

Ideally, the beam intensity should be flat, uniform and balanced across the cell array. As described above, at best in reality the light beam when incident upon the photo cell array has a semi-Gaussian profile in terms of its spot intensity. However generally even this will not be achieved. More likely the beam will exhibit a rather irregular profile due to optical irregularities inherent in the reflector assembly. In general what is referred to here as “beam flattening” is desirable. This means that the beam exhibits approximately the same intensity across its diameter. While difficult to achieve, this is the goal.

One way to minimize this irregularity and achieve a more uniform beam intensity profile is to use hexagonal minors instead of the conventional square (e.g., 1 cm to 2.54 cm square) minors in the reflector assembly. Moreover it has been found it is preferred to use a large number of relatively small mirrors as described above, such as about one inch square (2.54 cm) in size. This is not limiting.

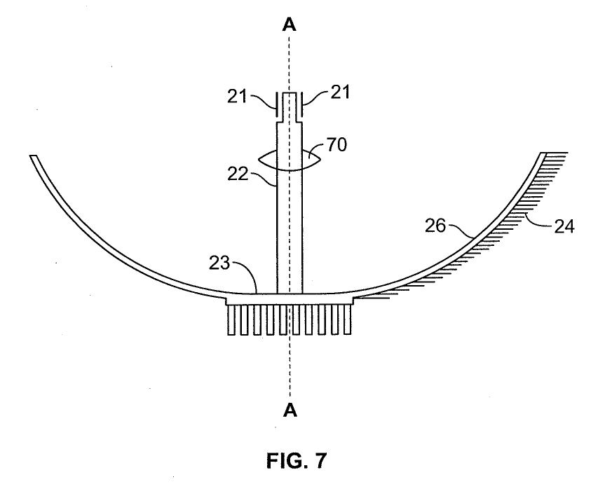

Another technique as shown in FIG. 7 (otherwise similar to FIG. 2 with like elements similarly labeled) is to provide a lens or lens assembly 70 in the optical path of the concentrated light beam in a solar concentrator apparatus of the types of e.g. FIGS. 1 and 2. While it is well known to use Fresnel lenses in this application, typically these Fresnel lens are what is referred to as “near field” in that they are located close to the reflector and relatively far from the solar cell array. Instead in accordance with the present invention, a Fourier transform lens assembly 70 is placed in the optical path of the light beam between the reflector 23 and the solar cell array (which may be of the type known in the prior art or as disclosed here) and which provides a “far field” effect being located relatively far from the reflector 23 and close to the solar cell array 21. The Fourier transform lens assembly 70 includes in one example a Fourier transform lens, followed by a low pass filter, followed by an inverse Fourier transform lens, all in optical path A-A.

Fourier transform optics are well known in the optical field. It is well known that if a transmissive object is placed one focal length in front of a lens, then its Fourier transform image will be formed one focal length behind the lens. This uses the lens as effectively a low pass plane wave filter. Generally the lens passes, from the object plane over on to the image plan, only that portion of the radiated spherical wave (light beam) which lies inside the edge angle of the lens.

Suitable Fourier transform lenses for lens assembly 70 are commercially available from vendors such as Control Optics in various diameters, for instance up to 235 mm in diameter. Typically these Fourier lenses are long focal length diffraction limited performance lenses that expand or reduce the optics input (light beam) without introducing any errors into the light beam. They are typically lens doublets (two lenses) in a single frame with a tilt adjustment provided. They are typically air spaced and ideally free of any aberration or a stigmatism. Such lenses are available for incoherent optics such as in the solar light collection technology of interest here. They are widely used for the beam transfer. In this case the exit aperture of the second Fourier lens is smaller than the entrance aperture of the first Fourier lens, producing a collimating effect on the light beam. It is expected here that in a typical example where the reflector assembly is approximately 1.2 meters in diameter, it will provide a two inch (50 mm) diameter light beam or somewhat larger. This would call for an approximately 50 mm diameter Fourier transform lens. This example is not limiting. Note that here some of the light beam energy is lost to improve beam profile uniformity.

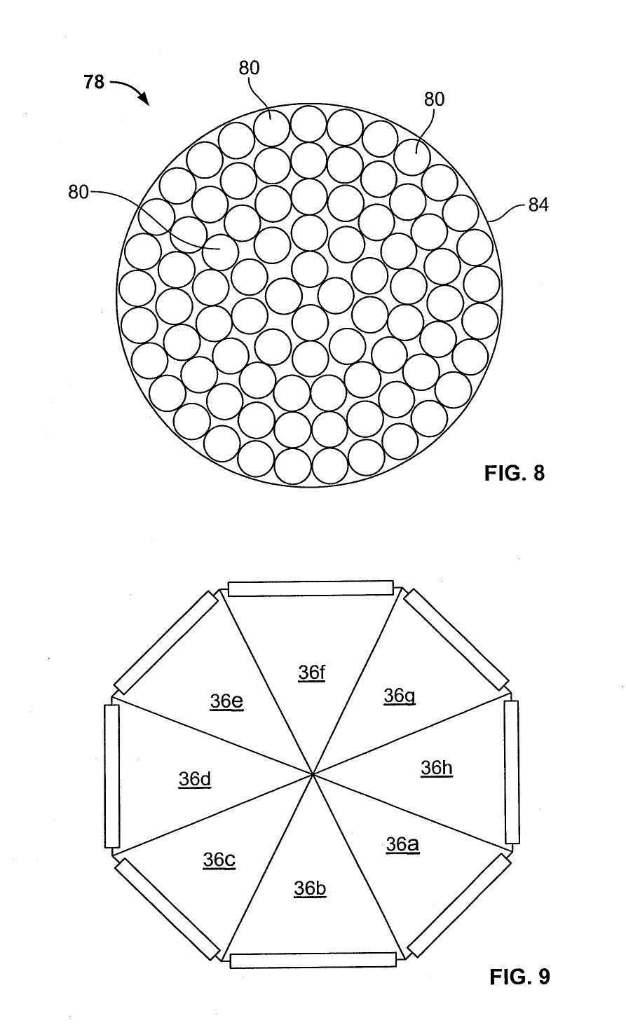

Instead of the lens 70 shown in FIG. 7, in another embodiment an optical device 78 as shown in FIG. 8 is used to alter the beam intensity profile by being located in the solar concentrator on the path of the optical beam so as to intercept the light beam incident from the reflector assembly and alter the beam intensity profile before passing the beam to the solar cell array. As seen end on in the figure, this device 78 is a large bundle of conventional optical fibers 80. The fibers 80 are e.g. each a few inches (1 to 8 cm) long and are bundled within a housing or enclosure 84. Seen here, the various fibers 80 are shown end on. The diameter of the device 78 here is somewhat larger than that of the incident beam and this optical fiber d bundle device 78 is located approximately in the same location as the Fourier transform lens 70 of FIG. 7. This configuration is also intended to compensate for the well known problem of solar flares and sun spots which will cause random time varying irregularities in the level of intensity of the light beam. It does this by performing a spatial smoothing function by randomly interleaving the bundled optical fibers.

So rather than each optical fiber being straight and of uniform length, some of the fibers may be interleaved with one another within their enclosure and also be of different lengths. That is, in terms of length some are shortened relative to others to match the wavefront of the incident light beam from the reflector assembly. The interleaving (braiding or twisting) is from the perspective of the incident light beam also, so as to disperse the outgoing light onto the cell array at different points than would be the case with the beam as incident on the optical fiber bundle. Again, the goal is to flatten the beam intensity profile when it reaches the solar cell array. This provides a spatial smoothing effect. The shortening and/or interleaving of selected ones of the fibers is done when the solar concentrator assembly is assembled, to even out the intensity of the light beam profile. That is, each optical fiber 80 will intercept a portion of the incident light beam. The interleaving and shortening are introduced by a technician in individual optical fibers during assembly of the solar concentrator to ensure that the overall beam intensity is relatively even across its entire diameter, thus achieving the above described beam flattening effect. This thereby “tunes” each individual solar concentrator since it is anticipated that minor manufacturing tolerances will result in the undesirable beam irregularities described above in addition to the problem of solar flares and spots.

In order to determine which fiber is to be shortened, the technician takes an interferometric image of the reflector (using an interferometer and a camera), and then examines the interference patterns/contours of the image, and thus of the reflector. The data enables the technician to determine which fibers need to be shortened and by how much to match the beam wavefront. Once the technician knows which fibers to shorten, he takes the bundle head and etches off the fibers that need to be shortened with a polisher. The entire process can be done automatically using a polishing system with feedback.

It has been found that in some embodiments, relatively random interleaves and shortening of the individual optical fibers 80 achieve a similar result as a more carefully tuned individual fiber tuning approach. Note that there may be hundreds of fibers in the bundle depending on the fiber and beam diameters.

Instead of the lens 70 shown in FIG. 7, yet another type of fiber bundle device as shown in FIG. 8 can improve the uniformity of the light beam profile. This is referred to here as a wave guide arrangement and acts as a collimator of the incident light beam using internal reflections. The inner fibers within the fiber bundle have no cladding and are spaced somewhat apart from one another and light will leak from one fiber onto the other and vice versa. The outer fibers of the bundle are provided with conventional cladding. So the collection of inner fibers within the outer fibers acts as a wave guide. Further the entire bundle is somewhat funnel shaped, so the upper end (where the light beam enters) is wider than the end where the light beam exits. The concept is that as the light beam enters the wave guide at various angles, normal incident light goes through the fiber, and the non-normal incident light will travel through several fibers before being reflected by the cladding of the outer fibers. Each time the light goes through the inner fibers, it leaks energy into the fiber it is travelling through. A glass with anti reflection coating (ARC) is placed on the top of the wave guide. The glass with ARC will introduce index matching to guide the light wave into the fiber bundle.

Other improvements are introduced here in the reflector assembly. As described above, in some embodiments these reflectors are a large number of small minors mounted on a parabolic support structure. It has been found that it is desirable to use mirrors which have a reflection coating or coatings to reflect both visible and infra-red light. Note that most solar cell assemblies now are intended to reflect and convert to electricity light in the visible spectrum. However at least some solar cells are also sensitive to infra-red light and by providing a suitable reflective coating on the minors one can collect infra-red light into the beam and project it onto the solar cells for higher energy conversion yields. An exemplary single coating to reflect both kinds of light is aluminum oxide; alternatively several layers of coatings can be used.

Also it has been found that a large number of relatively small mirrors as described above provides an advantageous low pass filtering effect adding to the above-described beam flattening effect.

The parabolic support for the reflector assembly as described above typically may be conventionally fabricated from metal, fiberglass, or similar materials. However as an alternative glass may be used as the support material. This glass is, e.g., laminated or tempered glass of the type for instance use in automobile windshields or windows, but of course need not have the same amount of mechanical strength since its only function is to support the relatively small minors. For instance, in one embodiment the parabolic support consists of a lamination of approximately 1 to 2 mm thick layer of glass laminated to a second 1 to 2 mm thick layer of glass by an intervening 0.5 to 1 mm thick layer of laminate where the reflection coating may be applied to the laminate. So the reflection coating is applied on the side facing the sun. Both the reflection coating and the lamination material are sandwiched between the two layers of glass which protects the reflection coating from the environment.

Since for instance automobile windshields and windows are produced in very large quantities by conventional molding, a similar process would substantially reduce the cost of fabricating the support while providing a reflector support which has an exact degree of parabolic curve and is relatively thermally stable and hence minimizes optical aberrations. Moreover, special geometries and curvatures can be applied to the glass to fit the geometry of square detectors. For example, a curved windshield type glass with equal straight sides of about 33 cm is suitable for matching the beam and concentrating it onto square detectors. (The 33 cm dimension is just as an example.) This could be used instead of a bowl type reflector.

In yet another aspect, in the solar cell array of FIG. 3 and as depicted in FIG. 9, the detected photocurrent (or a proxy for photocurrent such as the photo-voltage) from triangular photocell 36b is subtracted from the detected photocurrent of triangular photocell 36f to produce an error signal (using a suitable processor) that is used to mechanically drive the optical system (via suitable servo motors or by moving it manually) in such a way as to move the centroid of the illumination toward photocell 36f. Similarly, one could use a combination of photocell signals (i.e., the sum of currents from cells 36e, 36f, and 36g minus the sum of cells 36a, 36b, and 36c) to generate the error signal. This provides the above described feedback effect and also the above described defocus, astigmatism and coma corrections.

This disclosure is illustrative and not limiting; further modifications will be apparent to those skilled in the art in light of this disclosure and are intended to fall within the scope of the appended claims.

I claim:

1. A solar concentrator apparatus comprising:
a reflector assembly including a plurality of hexagonal planar reflectors and adapted to reflect incident sunlight into a beam of light; and
a photovoltaic cell array located to receive the beam of light and including:
a plurality of photovoltaic cells arranged around a central region;
a support for the cells; and
at least one electrical conductor in contact with each cell.

2. The apparatus of claim 1, wherein each hexagonal planar reflector includes a reflective coating adapted to reflect the incident sunlight in the infra-red and visible light bands.

3. The apparatus of claim 1, wherein the reflector assembly includes a parabolic or concave arrangement of the hexagonal planar reflectors.

4. The apparatus of claim 1, wherein the reflector assembly includes a laminated glass support on which the planar reflectors are mounted.

5. The apparatus of claim 1, further comprising a Fourier transform lens assembly located intermediate the reflector assembly and the cell array.

6. The apparatus of claim 5, further comprising an optical low pass filter in the Fourier transform lens assembly.

7. The apparatus of claim 1, further comprising a device including a bundle of optical fibers located intermediate the reflector assembly and the cell array, the optical fibers each being end on to both the reflector assembly and the cells array, wherein a first plurality of optical fibers are shorter relative to others and some of the optical fibers are interleaved with one another, thereby to alter an intensity profile of the beam incident on the cell array.

8. A method of operating a solar concentrator including an optical collector assembly adapted to direct incident sun light into a beam of light incident on a photovoltaic cell array, comprising the acts of:
determining an intensity profile of the beam of light; and
altering the profile so as to increase a uniformity of the beam of light incident on the array.

9. The method of claim 1, wherein the act of altering includes at least one of applying a Fourier optical transform, low pass optical filtering, subjecting the beam to interleaving, or subjecting the beam to a waveguide.
